(19) United States
(12) Patent Application Publication
(10) Pub. No.: US 2025/0107002 A1
(43) Pub. Date: Mar. 27, 2025

(54) APPARATUS AND METHOD FOR PCB FIXATION WITH BATTERY TABS IN A HOUSING

(71) Applicant: CONTINENTAL AUTOMOTIVE TECHNOLOGIES GMBH, Hannover (DE)

(72) Inventors: Ilie Atanasoe, Timisoara (RO); Monica Nagy, Seini (RO)

(73) Assignee: Continental Automotive Technologies GmbH, Hannover (DE)

(21) Appl. No.: 18/729,052

(22) PCT Filed: Jan. 9, 2023
(86) PCT No.: PCT/EP2023/050294

§ 371 Date: Jul. 15, 2024

(30) Foreign Application Priority Data
Jan. 17, 2022 (EP) 22465502.7
Jan. 17, 2022 (EP) 22465503.5
Jan. 18, 2022 (GB) 2200576.3
Jan. 18, 2022 (GB) 2200577.1

(51) Int. Cl. H05K 1/18; B60C 23/04

(52) U.S. Cl. CPC H05K 1/18; B60C 23/041; H05K 2201/10037; H05K 2201/10393

(57) ABSTRACT

A PCB holder for holding a PCB, and a method of assembling such a holder, are disclosed. The holder comprises a housing and at least one deflectable electrically-conductive tab or prong with a deflectable proximal end configured for retaining and exerting pressure on the edge of a PCB and a distal end mechanically secured to a pole of a battery, and a deflectable middle portion connecting the proximal end and the distal end, wherein the at least one deflectable electrically-conductive terminal prong is configured to deflect during insertion of the PCB and exert a compressive securing force on an operably inserted PCB.

### CROSS-REFERENCE TO RELATED APPLICATIONS

The present application is a National Stage Application under 35 U.S.C. § 371 of International Patent Application No. PCT/EP2023/050294 filed on Jan. 9, 2023, and claims priority from European Patent Application Nos. 22465502.7 and 22465503.5 filed on Jan. 17, 2022, in the European Patent Office and UK Patent Application Nos. 2200576.3 and 2200577.1 filed on Jan. 18, 2022, in the Intellectual Property Office of the United Kingdom, the disclosures of which are herein incorporated by reference in their entireties.

### BACKGROUND

### 1. Field

Aspects and objects of embodiments of the present application relate to electronic device components and, in particular, to battery holders and Printed Circuit Board (PCB) holders for Tire Pressure Monitoring Systems (TPMS) and related methods.

### 2. Description of Related Art

TPMS devices include a PCB and a battery to supply electrical power. These components can be joined together with electrically conductive metal tabs. The tabs may be held in place on the PCB with solder. A main disadvantage of such a construction is the necessity to build complex fixtures to align the tabs on the soldering pads when the soldering operation is done outside of the housing. Performing the soldering operation inside the housing may not be possible. In addition, there is a risk of creating solder balls or other imperfections when performing the soldering. Likewise, additional time and verification may be needed to insure quality.

When clips are used to hold a PCB and battery in place, this may require a complex manufacturing process for the housing and the exertion of high forces on the PCB during assembly, which can lead to cracks in sensitive components. In case of fixation with glue there are lead times for glue curing in the oven and the glue deposition may be a lengthy or costly process.

### SUMMARY

According to an embodiment of the present application, there is provided a PCB holder for holding a PCB, comprising a housing, and at least one deflectable electrically-conductive prong, with a deflectable proximal end configured for retaining and exerting pressure on the edge of a PCB, and a distal end mechanically secured to a pole of a battery, and a deflectable middle portion connecting the proximal end and the distal end, wherein the at least one deflectable electrically-conductive prong is configured to deflect during insertion of the PCB and exert a compressive securing force on an operably inserted PCB.

In embodiments, an electronic device battery and PCB holder comprises tabs or prongs for connecting to a battery with a positive pole and a negative pole, and for holding a PCB. One or more of the tabs or prongs may comprise a simple bent clip-like feature and a projection. On the PCB, grooves in the edge may be milled and plated, as contact surfaces for the tabs. In this way mechanical and/or electrical links are created using the clip shapes of the tabs.

The additional prong or spring shapes can be implemented as bent flanges of metal sheet. Thus, they can be easy to manufacture and can assure a good PCB fixation. In embodiments these battery tabs may have a double function of energy supply and fixing elements in the housing. In general, electrically-conductive materials bring good mechanical characteristics for the inventive solution.

The PCB holder comprises at least one deflectable electrically-conductive terminal prong configured to exert a force on the PCB operably inserted into the electronic device holder, to contact a pole of the battery, and to securely support and hold the PCB in the holder. At least one of the deflectable electrically-conductive terminal prongs is configured to deflect during insertion of a PCB therein and exert a compressive securing force on an operably inserted PCB while being mechanically stabilized by a mechanical connection to a positive or negative pole of a power supply or battery, and by spring-like projection features of the battery tabs or prongs.

In embodiments, the deflectable proximal end may include a hook portion configured to provide a contact to the PCB, and a release surface configured for a user to press, thereby defecting the deflectable proximal end and releasing the PCB.

The force exerted by the deflectable electrically-conductive terminal prongs may hold the PCB against the respective other prong.

The at least one deflectable electrically-conductive terminal prong may have a distal end, and the distal end of the at least one deflectable electrically-conductive terminal prong may be configured for mechanical connection to a pole of a battery.

The PCB may be a PCB of a TPMS for determining operating characteristics of a tire or wheel, such as tire pressure, temperature, and radial or axial velocity or acceleration. The PCB holder may be inserted in a housing to form a TPMS.

The at least one deflectable electrically-conductive positive or negative terminal prong may consist of a plurality of deflectable electrically-conductive positive or negative terminal sub-prongs or sub-tabs, all of which are electrically connected. Each of the plurality of deflectable electrically-conductive positive or negative terminal sub-prongs may have a proximal end configured for providing an electrical connection to a PCB.

The battery may be a coin cell battery. The battery may be generally cylindrical in shape.

The complete assembly, including one or more of PCB, antenna, battery and tabs, may be maintained in a plastic housing using the spring-like projection features of the battery tabs or prongs. In embodiments, these projections will engage in the helical ribs of the housing. In embodiments, the projections assure PCB fixation during a potting or gluing operation.

According to an aspect of an embodiment, there is provided a method for assembling a PCB holder, comprising inserting a PCB between two deflectable electrically-conductive prongs, and inserting the resulting assembly into the housing.

In embodiments, the method for using or assembling an electronic device holder comprising: operably inserting a PCB into an electronic-device holder such that at least one deflectable electrically-conductive terminal prong of the PCB holder deflects during the insertion, and exerts a securing force on the operably inserted PCB, and contacts a positive or negative pole of the battery or power supply. In embodiments, the method comprises releasing the operably inserted PCB by depressing a release surface of the at least one deflectable electrically-conductive positive terminal prong, thereby removing the compressive securing force and such that the force of the deflectable electrically-conductive terminal prong releases the PCB from operable insertion in the PCB holder.

The at least one deflectable electrically-conductive terminal prong may have a deflectable proximal end that includes a hook portion configured to provide the contact to the PCB and the release surface, and spring-like projection features.

The force exerted by the at least one deflectable electrically-conductive terminal prong may hold the PCB against a PCB holder or hook of the housing.

In embodiments, an additional feature in the housing serves to secure the contact between the tabs and the PCB.

Each deflectable electrically-conductive terminal prong or tab may have a proximal end, wherein the proximal end of the at least one deflectable electrically-conductive terminal prong may be configured for electrical connection to a printed circuit board PCB.

### BRIEF DESCRIPTION OF THE DRAWINGS

The advantages of the mechanisms and methods described herein may be better understood by referring to the following description in conjunction with the accompanying drawings, in which:

FIGS. 1A and 1B are diagrams illustrating an approach for fixing a PCB using clips or glue;

FIG. 2 shows an embodiment of the inventive concept;

FIG. 3 shows a second embodiment of the inventive concept;

FIG. 4 shows the steps of the inventive method;

FIG. 5 shows a third embodiment of the inventive concept, and

FIG. 6 shows a fourth embodiment of the inventive concept.

### DETAILED DESCRIPTION OF ILLUSTRATIVE EMBODIMENTS

The following detailed description should be read with reference to the drawings, in which like elements in different drawings are like numbered.

The drawings, which are not necessarily to scale, depict exemplary embodiments for the purpose of explanation only and are not intended to limit the scope of the embodiment. The detailed description illustrates by way of example, not by way of limitation, the principles of the embodiment. This description will clearly enable one skilled in the art to make and use the embodiment, and describes several embodiments, adaptations, variations, alternatives and uses of the embodiment, including what is presently believed to be the best mode of carrying out the embodiment.

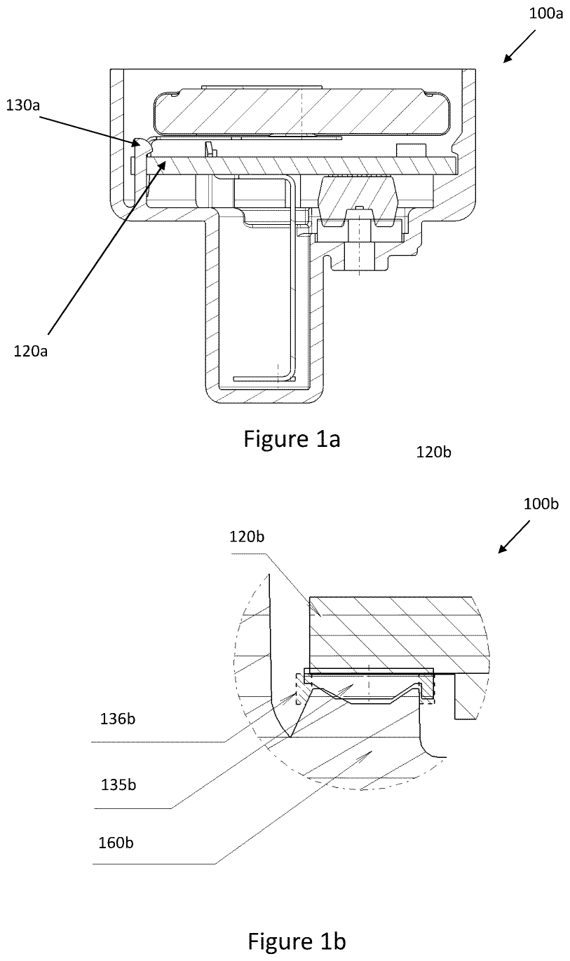

In FIGS. 1a and 1b is shown an approach for fixing a PCB, aspects of which may be known to the person of skill. The PCB 120a, 120b is positioned in the housing 160b such that it is in contact with supports integrated in the housing. In FIG. 1a, a tab 120a retains the PCB. In FIG. 1b, glue 135b, 136b is used to fix the PCB in position, such that it is fixedly attached to the housing.

In other known embodiments, the PCB may be fixed to the housing with separate clips, screws, or other fasteners. It is also known to use a combination of these fastening elements, with or without glue. In the case of a plastic housing, it is also known to use additional plastic elements which are welded to the plastic of the housing.

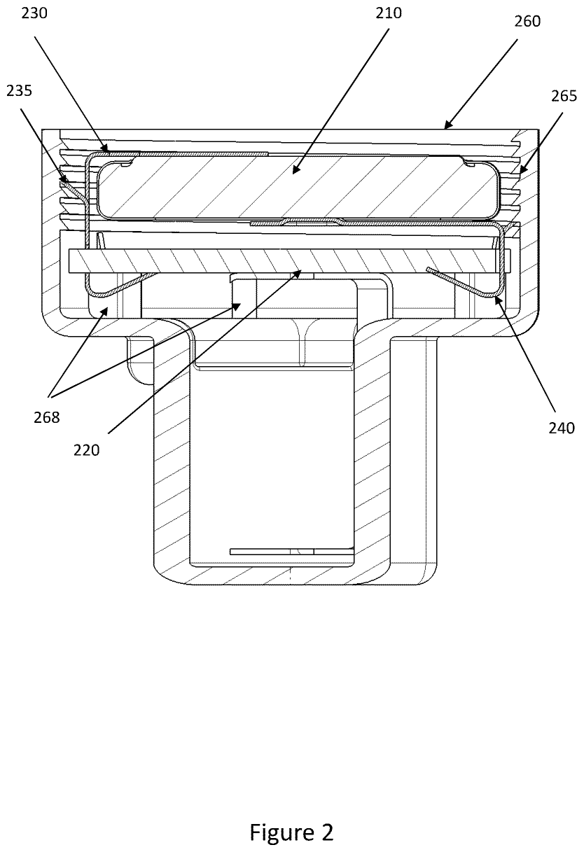

In FIG. 2 is shown an embodiment of the inventive concept. An electrically conductive prong or tab 230 is attached and mechanically secured to a battery 210. The attachment may be both a mechanical and an electrical attachment. The attachment to the battery may advantageously be with welding or soldering. The prong or tab comprises a hook or indentation or other feature positioned and shaped to secure the PCB 220 using a certain deflection force exerted by flexing the tab. A second tab is shown as 240.

In embodiments, the tab or tabs exert a force on the PCB which brings it in contact with one or more posts or features 268 on the inside of the housing 260, which features serve to stabilize the PCB and keep it from moving. The features may have a notch shape, or be posts which rise from the housing, or other shapes which serve as a base or stand to position the PCB.

In embodiments, a projection 235 on the prong or tab is positioned to engage with retention features 265 on the inside wall of the housing 260. In this embodiment shown, the retention features use a spiral form such as a thread, but the retention features may also take the form of a ladder or indentations or other forms. The inventive concept does not require retention features, especially if the tabs or prongs are able to achieve a retention force on the inside wall of the housing. This might be the case if the tabs are stiff, and the inside wall of the housing is comparatively soft.

The projection on the prong is formed with an angle such that it is encouraged to deflect on insertion into the housing, and to not deflect under the influence of a force in a direction which would remove it from the housing. Thus, the prong is fixed in the housing in a stable manner.

The projection may be sized and positioned such that it is in contact with the housing when a PCB is present, and not in contact with the housing if no PCB is present. The projection may be sized and positioned such that it exerts substantially more force on the retention feature or on the inside wall of the housing when the PCB is inserted, such that it is much easier to remove the prong or tab from the housing when no PCB is present.

In embodiments, the PCB may receive power via a positive and/or negative prong electrically connected to the battery or power supply. The prong may serve a dual purpose of retaining the PCB in position and supplying power to the PCB.

In embodiments, the PCB may be retained on both sides by a prong or tab which passes from one side of the PCB to the battery or power supply and on to the other side of the PCB. The tab may exert a deflective force on one or both sides of the PCB. The tab may advantageously be electrically and mechanically connected to the negative pole of a button battery.

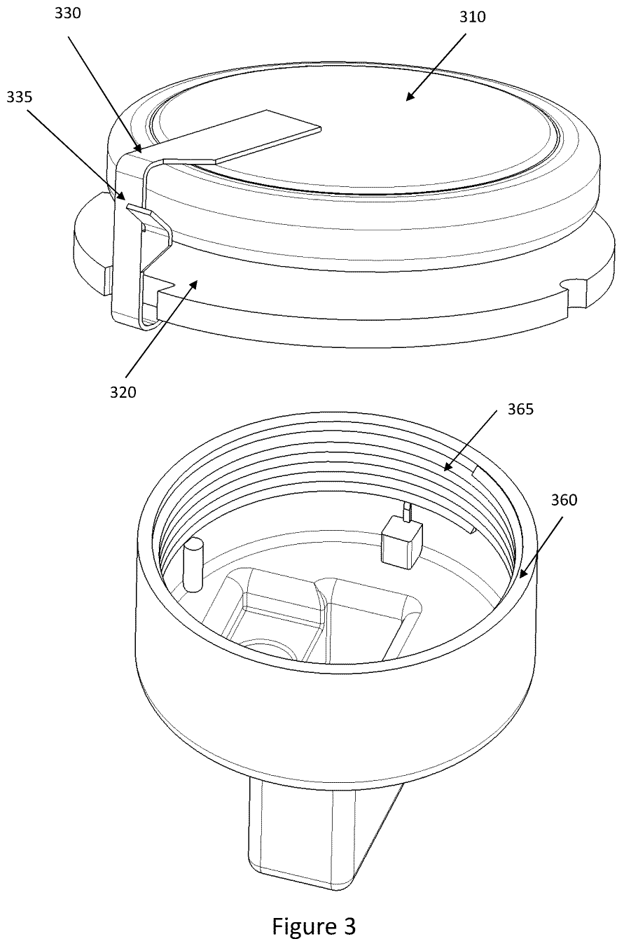

In FIG. 3 is shown an additional embodiment of the inventive concept, prior to assembly of the battery+PCB+tabs in the housing. The prong or tab 330 is formed in such a way that it includes a hook or indentation to engage with and exert a force on a PCB 320, and then terminates with a projection 335 which engages with and exerts a force on retention features 365 on the inside wall of the housing 360.

In general, PCB holders for holding a PCB with mechanical attachment to a positive pole and a negative pole (such as a coin cell battery) according to embodiments of the present embodiment include at least one deflectable electrically-conductive positive terminal prong with a deflectable proximal end configured for mechanical connection to a PCB (Printed Circuit Board), a fixed distal end configured for fixed attachment to a pole of a battery, and a deflectable middle portion connecting the proximal and distal ends. The PCB holder may also include at least one second deflectable electrically-conductive terminal prong or tab configured to also exert a securing force on a PCB, in contact with the other pole of the battery, to securely support and hold the PCB.

PCB holders according to embodiments of the present embodiment are beneficial in that, for example, they include a minimal number of components (thereby simplifying handling and assembly) and do not require the inclusion or use of a dedicated battery housing, plastic cover and/or battery holder. The inclusion of a minimal number of parts results in a beneficially inexpensive electronic device with improved reliability. This is of particular importance for TMPS devices.

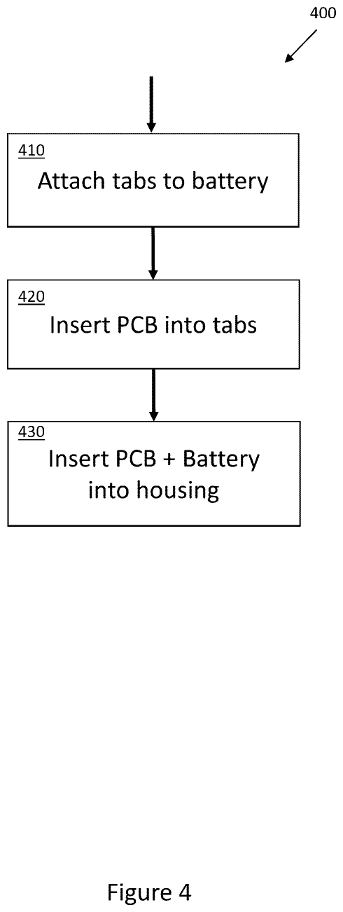

FIG. 4 is a flow diagram depicting stages in an exemplary method 400 for using or of assembling a PCB holder. Method 400 includes, at step 410 of FIG. 4, mechanically attaching or fixing two tabs or prongs to a battery. In step 420, the PCB is inserted into the tabs or prongs. The operable insertion is such that (i) the deflectable electrically-conductive terminal prong connected to the positive battery pole deflects during the insertion, and exerts a compressive securing force on the operably inserted PCB; and (ii) the deflectable electrically-conductive terminal prong connected to the negative pole of the battery is deflected, and exerts a force on the operably inserted PCB (e.g., a securing force that holds the PCB in the assembly). Then at step 430, the assembly with battery, prongs and PCB is inserted into the holder.

In embodiments, the battery may be provided with prongs attached. In such embodiments the method begins with step 420.

In further steps, for example at a later time, the assembly of PCB, battery and tabs may be removed from the holder.

PCB holders according to embodiments of the present embodiment can be manufactured using any suitable techniques including, for example, metal stamping and forming techniques. Deflectable electrically-conductive prongs or tabs can, for example, be formed of a predetermined configuration from a thin metal plate. Deflectable electrically-conductive prongs or tabs employed in embodiments of the present embodiment can be formed from any suitable materials including, for example, carbon steel, beryllium copper, stainless steel, phosphor bronze materials. In addition, the thickness of such materials can be, for example, in the range of 0.2 mm to 0.5 mm.

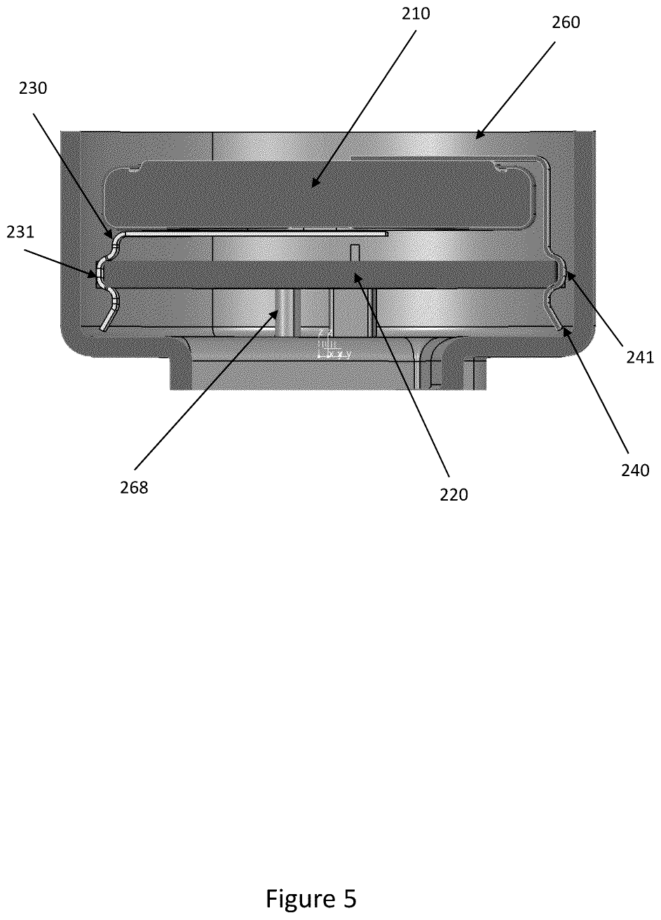

FIG. 5 shows a further embodiment of the inventive concept. An electrically conductive prong or tab 230 is attached and mechanically secured to a battery 210. The attachment is both a mechanical and an electrical attachment. The attachment to the battery may advantageously be with welding or soldering. The prong or tab comprises a hook or indentation or other feature positioned and shaped to secure the PCB 220 using a certain deflection force exerted by flexing the tab. A second tab is shown as 240.

The tabs have a contact area 231, 241 shaped to insure electrical contact with the PCB 220. The prongs or tabs 230, 240 are connected to two poles of the battery 210, and insure both a mechanical hold and an electrical connection.

In embodiments, the tab or tabs exert a force on the PCB which brings it in contact with one or more posts or features 268 on the inside of the housing 260, which features serve to stabilize the PCB and keep it from moving. The features may have a notch shape, or be posts which rise from the housing, or other shapes which serve as a base or stand to position the PCB.

In embodiments, the PCB may receive power via a positive and/or negative prong electrically connected to the battery or power supply. The prong may serve a dual purpose of retaining the PCB in position and supplying power to the PCB.

In embodiments, the PCB may be retained on both sides by a prong or tab which passes from one side of the PCB to the battery or power supply and on to the other side of the PCB. The tab may exert a deflective force on one or both sides of the PCB. The tab may advantageously be electrically and mechanically connected to the negative pole of a button battery.

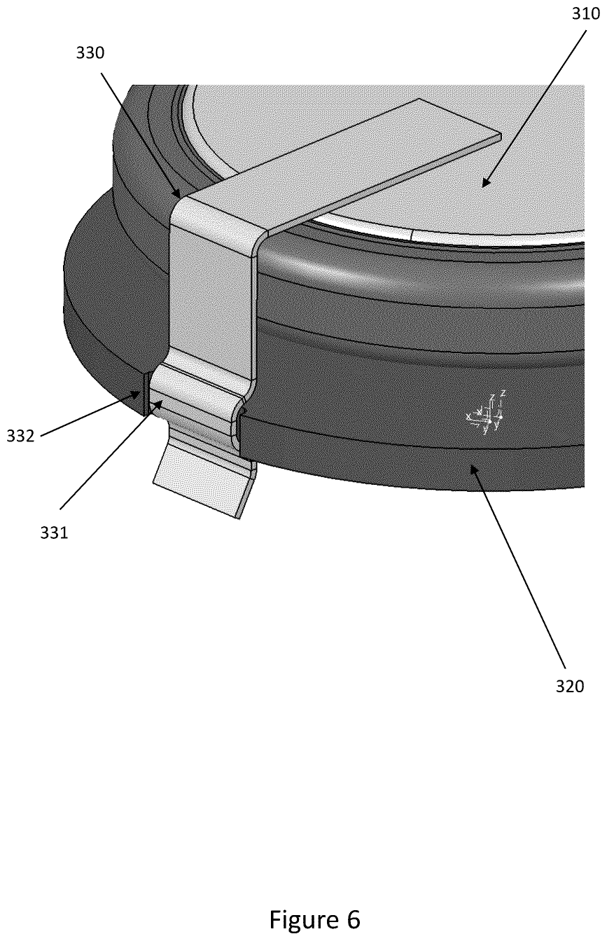

In FIG. 6 is shown an additional embodiment of the inventive concept, prior to assembly of the battery+PCB+tabs in the housing. The prong or tab 330 is formed in such a way that it includes a hook or indentation 331 to engage with and exert a force on the PCB 320 at the point of a notch 332. The contact between indentation 331 and notch 332 insures both mechanical retention and electrical contact between the PCB and the battery 310.

1. A printed circuit board (PCB) holder comprising:
a housing; and
a deflectable electrically-conductive prong comprising:
a deflectable proximal end configured for retaining and exerting pressure on the edge of a PCB;
a distal end mechanically secured to a pole of a battery; and
a deflectable middle portion connecting the proximal end and the distal end,
wherein the at least one deflectable electrically-conductive prong is configured to deflect during insertion of the PCB and exert a compressive securing force on an operably inserted PCB.

2. The PCB holder of claim 1, further comprising two electrically-conductive prongs mechanically secured to positive and negative poles of the battery.

3. The PCB holder of claim 1, wherein the deflectable proximal end of at least one prong comprises a hook or indentation portion configured to retain the PCB.

4. The PCB holder of claim 3, wherein force exerted by the proximal end of the deflectable prong holds the PCB against features of the housing.

5. The PCB holder of claim 1, wherein the at least one deflectable prong comprises a projection, and the projection is formed with an angle to deflect upon insertion into the housing, and to not deflect under the influence of a force in a direction from the housing.

6. The PCB holder of claim 5, wherein a projection on at least one prong is positioned to engage with retention features on the inside wall of the housing.

7. The PCB holder of claim 6, wherein the retention features have a spiral form.

8. The PCB holder of claim 2, wherein the distal end of the at least one deflectable electrically-conductive prong connected to the positive pole and the distal end of the at least one deflectable electrically-conductive prong connected to the negative pole are configured for electrical connection to the PCB.

9. The PCB holder of claim 8, wherein the deflectable electrically-conductive prongs are configured to deflect during insertion of the PCB and make electrical contact with and exert a compressive securing force on the operably inserted PCB.

10. The PCB holder of claim 1, wherein the battery is a coin cell battery.

11. The PCB holder of claim 1, wherein at least one deflectable electrically-conductive prong is secured to the battery by an attachment of welding or soldering.

12. The PCB holder of claim 1, wherein at least one deflectable electrically-conductive prong consists of a plurality of deflectable electrically-conductive sub-prongs.

13-14. (canceled)
